(19) United States
(12) Patent Application Publication
(10) Pub. No.: US 2006/0124970 A1
(43) Pub. Date: Jun. 15, 2006

(54) Device for data exchange between a transmitter and a receiver

(76) Inventor: Marcus Heilig, Mossingen (DE)

Correspondence Address: Ronald R santucci;Frommer Lawrence & Haug, 745 Fifth Avenue, New York, NY, 10151, US

(21) Appl. No.: 10/540,780

(22) PCT Filed: Dec. 19, 2003
(86) PCT No.: PCT/IB03/06277

§ 371 Date: Dec. 19, 2005

(30) Foreign Application Priority Data
Jan. 10, 2003 (FR) 03 00263

(51) Int. Cl. H01L 29/768

(52) U.S. Cl. 257/222

(57) ABSTRACT

The inventive data exchange device comprises a transmitter (SA4) fed by a power supply (VDDA), an electric cable (C1) whose first conducting wire is connected to a fixed potential point (GNDA) of the transmitter and second conducting wire is connected to a variable potential point of the transmitter and a receiver (SB4). Said receiver (SB4) comprises a component (DZB4) which defines a voltage threshold opposite to the direction of electric current in the cable (C1). Said device is embodied in such a way that it is simple and low-cost in the production thereof. The device makes it possible to interconnect a plurality of transmitters and receivers and is low sensitive with respect to voltage and parasite currents.

### FIELD OF THE INVENTION

The invention relates to an installation for exchanging information comprising a transmitter supplied from a power supply, an electric cable of which a first conductor is connected to a point of fixed potential of the transmitter and of which a second conductor is connected to a point of variable potential of the transmitter and at least one receiver.

Such installations are widely used for exchanging information. They require, on the one hand, the use of shielded cables or pairs of twisted wires, protected against electromagnetic radiations and, on the other hand, the use of circuits for generating signals constituting the information and for shaping these signals. Data transmission installations using the EIB (registered trademark), LONWORKS (registered trademark) or RS485 standards, for example, are known. Such systems are very competitive and make it possible to transmit information with a high bit rate. However, these installations are overdimensioned for certain applications in which, in particular, a high bit rate is not an important criterion.

### PRIOR ART

Simpler installations are known from the prior art. For example, an assembly such as that represented in FIG. 1 is known. This assembly comprises a transmitter SA1 and a receiver SB1 linked to one another by an electric cable C1 with two conductors whose electrical resistances are symbolized by the resistors RL1 and RL2. The transmitter mainly comprises a controlled switch consisting of a transistor TA1 operating in switch mode and making it possible to connect together or not the two ends of the conductors of the electric cable. The receiver SB1 itself comprises a power supply providing a voltage VDDB linked to the end of one of the conductors of the electric cable via a resistor RB1. A voltage Us is measured between the ends of the conductors of the electric cable. This voltage Us varies according to the state of the transistor of the transmitter SA1. Thus, an item of information is coded as a succession of states of the transistor TA1 at the level of the transmitter and decoded by measuring the variations of the voltage Us at the level of the receiver SB1. When the transistor TA1 is on, the current intensity in the electric cable linking the transmitter and the receiver is mainly limited by the resistor RB1. The information bit rate being fairly low, it is unnecessary to represent on this diagram the capacitive and inductive effects of such an arrangement.

Such an installation has drawbacks. Specifically, if one envisages connecting 100 receivers with the transmitter SA1 on the same line, the current limiting resistors are arranged in parallel and their value then equals RB1/100. In order to avoid causing overly large currents to flow through the transistor TA, it is then necessary to limit the number of elements that can intercommunicate or to choose a large resistance RB1, for example 100 times the value causing the maximum current allowable by the transistor TA.

It is known that in such installations, common-mode voltages and differential-mode voltages appear at the level of the transmitters and receivers, in particular when the latter are distantly separated.

The common-mode voltages are represented by the arrows Ucm. On account of the resistance RB1, a common-mode current necessarily causes a modification of the voltage Us.

The differential-mode voltages are caused by currents Idm flowing around the loop formed by the two conductors of the electric cable between the transmitter and the receiver. These currents passing through the resistors RL1 and RL2 likewise contribute to modifying the voltage Us.

To reduce the effects of the interference induced currents Idm, shielded or twisted electric cables are used. In addition, conductors exhibiting a very small resistance are used and the allowable distance separating the various elements of the installation is restricted.

A compromise must be found regarding the value of the resistor RB1. Its value must be high so as to allow communication between a maximum of elements and to maintain, when the transistor TA1 is on, a voltage Us below the upper threshold of the low logic value of any logic circuit using this voltage. Conversely, its value must be small so as to limit the effects of the induced currents.

Installations such as that represented in FIG. 2 are also known. This assembly comprises a transmitter SA2 and a receiver SB2 linked to one another by an electric cable C1 with two conductors whose electrical resistances are symbolized by the resistors RL1 and RL2. The transmitter SA2 mainly comprises a power supply providing a voltage VDDA supplying a resistor RA and a transistor TA2 arranged in series. The transistor TA2 is controlled by a circuit (not represented) and operates in switch mode. The receiver SB2 mainly exhibits a resistor RB2 between the ends of the two conductors of the electric cable. The voltage Us is taken at the terminals of this resistor. Thus, an item of information is coded as a succession of states of the transistor TA2 of the transmitter and decoded by measuring the variations of the voltage Us in the receiver SB2. When the transistor TA2 is off, the current intensity in the electric cable linking the transmitter and the receiver is mainly limited by the resistor RA.

In this installation, the value of the resistor RB2 must, likewise, be large so as to allow the connection of a large number of elements, the value of RA being given. It must also be much greater than the values of the resistors RL1 and RL2. However, the value of RB2 must be as small as possible so as to reduce the effects of the common-mode and differential-mode induced currents.

### SUMMARY OF THE INVENTION

The aim of the invention is to produce an installation for transmitting information alleviating the drawbacks cited and improving the installations known from the prior art. In particular, the invention proposes to produce a simple installation whose manufacturing costs are low, making it possible to interconnect numerous transmitters and receivers that are insensitive to interference currents and voltages.

The installation for exchanging information according to the invention is characterized in that the receiver or the receivers comprise a component defining a threshold voltage opposing the flow of the electric current through the cable. Thus, the interference voltages must be greater than this threshold voltage in order to bring about the flow of a current around the cable and be interpreted as information.

The dependent claims 2 to 5 define various alternative embodiments of the installation according to the invention.

### BRIEF DESCRIPTION OF THE DRAWINGS

The appended drawing represents, by way of examples, two embodiments of an installation for exchanging information according to the invention.

FIGS. 1 and 2 represent transmitter-receiver assemblies known from the prior art, linked by electric cables allowing the exchange of information.

FIG. 3 represents a first embodiment of an installation for exchanging information according to the invention, comprising a transmitter and a receiver linked by an electric cable.

FIG. 4 represents a second embodiment of an installation for exchanging information according to the invention, comprising a transmitter and a receiver linked by an electric cable.

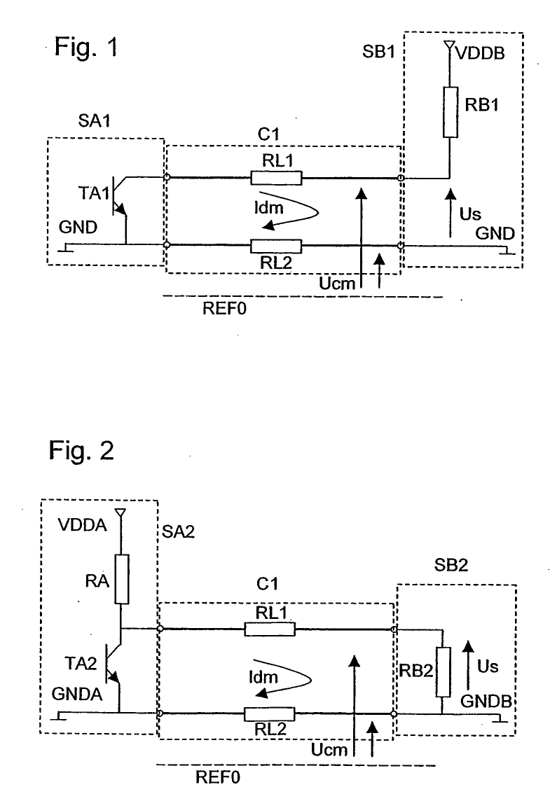

### DESCRIPTION OF THE PREFERRED EMBODIMENT

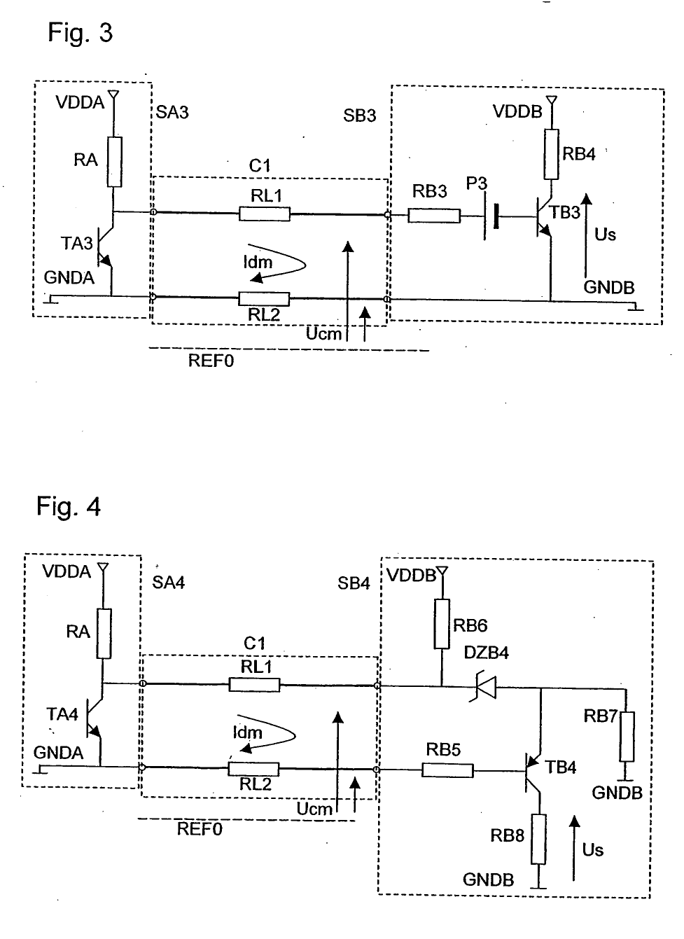

The first embodiment of the installation for exchanging information according to the invention is represented in FIG. 3 and comprises a transmitter SA3 and a receiver SB3 linked to one another by an electric cable with two conductors whose electric resistances are symbolized by the resistors RL1 and RL2. The transmitter SA3 comprises a transistor TA3 and is identical to the transmitter SA2 previously described. The receiver SB3 comprises a voltage supply VDDB supplying a resistor RB4 and a transistor TB3 arranged in series. The base of the emitter TB3 is linked to an end of a conductor of the electric cable via a DC voltage generator P3 such as a dry-cell or an electric accumulator and a resistor RB3. The transistor TA3 is controlled by a circuit (not represented) and operates in switch mode. The voltage Us is gathered between the emitter and the collector of the transistor TB3.

Thus, an item of information is coded as a succession of states of the transistor TA3 of the transmitter and decoded by measuring the variations in the voltage Us in the receiver SB2. When the transistor TA3 is off, the current intensity in the electric cable linking the transmitter and the receiver is mainly limited by the resistor RB3.

With such an arrangement it is possible to choose a large resistance RB3 while being insensitive to the effects of the induced currents. The transistor TB3 remains, in fact, off when the differential-mode voltage does not become greater than the voltage of the generator P3 plus the voltage between the base and the emitter of the transistor TB3.

For example, the voltages VDDA and VDDB of the power supplies of the transmitter SA3 and of the receiver SB3 may be equal to 12 V. The resistances RA and RB4 may be taken equal to 1 kΩ and RB3 equal to 50 kΩ so as to allow the interconnection of numerous elements. The voltage of the generator may be taken equal to 4.5 V and the base-emitter voltage of the transistor TB3 equal to 0.6 V.

Thus, the differential voltage allowing the change of state of the transistor equals substantially 5 V. This value gives a good safety margin making it possible to prevent the effects of the induced currents.

Such an arrangement has the drawback of using a DC voltage generator such as an electric cell or an accumulator. In the latter case, it will be noted however that the accumulator is recharged continuously across the resistors RA, RL1, RB3 and RL2 when the transistor TA3 is open, thereby compensating for autodischarge and giving the component a long lifetime.

In such a circuit it is not possible to replace this generator with a Zener diode of Zener voltage equal to 4.4 V in order to circumvent the interference voltages.

Specifically, if the generator P3 is replaced with a Zener diode, when the transistor TA3 is off, the current is mainly limited by the resistor RB3 and equals substantially: (12−5)/50=0.140 mA. Such a low value has the consequence that the voltage across the terminals of the Zener diode is very different from the Zener voltage and is in this case substantially zero. As a result, the circuit is sensitive to the induced currents.

A second embodiment of an installation, represented in FIG. 4, makes it possible to solve this problem. This installation comprises a transmitter SA4 and a receiver SB4 linked together by an electric cable C1 with two conductors whose electrical resistors are symbolized by the resistors RL1 and RL2. Information consisting of electric signals sent over the electric cable may be transmitted by the transmitter SA4 and be received by the receiver SB4. A single transmitter and a single receiver have been represented in FIG. 4 with the aim of simplification and clarity. However, it is obvious that the installation can comprise several command transmitters and several command receivers linked in parallel on the electric cable. For example, in a home automation network, such an installation allows communication between control devices, electrical equipment and sensors. Each of its elements can comprise a transmitter and a receiver so as to be able to carry out bidirectional communications between them.

The transmitter SA4 mainly comprises a power supply providing a voltage VDDA supplying a resistor RA and a transistor TA4 arranged in series. The transistor TA4 is controlled by a circuit (not represented) and operates in switch mode. The receiver SB4 comprises a power supply providing a voltage VDDB and supplying a resistor RB6 and a Zener diode DZB4 arranged in series with two parallel branches comprising respectively, a resistor RB7, and a transistor TB4 and a resistor RB8 arranged in series. One of the two ends of the conductors of the electric cable is connected between the resistor RB6 and the Zener diode, the other is connected to the base of the transistor TB4 by way of a resistor RB5.

The installation may be embodied, for example, with the following values:

VDDA=VDDB=12 V

RA=RB6=1 kΩ

UZ=3.9 V

RB5−47 kΩ

RB7=4.7 kΩ

RB8=100 kΩ

An item of information which is to be sent from the transmitter SA4 to the receiver SB4 is coded as a temporal succession of off and on states of the transistor TA4. It is decoded in the receiver SB4 by analyzing the variations in the voltage Us that is measured across the terminals of the resistor RB8.

When the transistor TA4 is off, a voltage is present between the collector and the emitter of the transistor TA4. This voltage equals substantially some 12 volts. It causes the flow of a current passing through the resistor RL1, the Zener diode DZB4, the transistor TB4, the resistor RB5 and the resistor RL2. The Zener voltage of the diode DZB4 is maintained by a current flowing across the resistors RB6 and RB7 wired between the power supply terminals of the receiver SB4. This Zener voltage and the emitter-base voltage of the transistor TB4 oppose the flow of the current through the cable. When a sufficient current flows through this cable, the transistor TB4 is on and the voltage Us then equals some 10 volts and is interpreted as a high state by a logic circuit. The large value of the resistor RB5 allows limitation of the current and the possibility of connecting a transmitter with numerous receivers.

When the transistor TA4 is on, the voltage between its collector and its emitter is substantially zero. This has the consequence that no current flows around the loop. The transistor TB4 is consequently off and the voltage Us is substantially zero. This is interpreted as a low state by a logic circuit. The current passing through the Zener diode and making it possible to maintain the Zener voltage at its terminals is chosen to be around 10 times greater than the induced currents that may be encountered in the cable. This makes it possible to ensure that induced interference currents cannot make the transistor TB4 switch into an on state.

Such an installation comprising some 100 receivers and a length of connection cable of 1000 m operates perfectly.

The transmitters and the receivers may of course comprise other elements such as capacitors. The transistor TA4 may, for example, be controlled by a microcontroller.

To allow the connection of an even larger number of elements in the installation, the resistor RA can also be replaced by a transistor.

1. An installation for exchanging information comprising a transmitter (SA3; SA4) supplied from a power supply (VDDA), an electric cable (C1) of which a first conductor is connected to a point of fixed potential (GNDA) of the transmitter and of which a second conductor is connected to a point of variable potential of the transmitter and at least one receiver (SB3; SB4), wherein the receiver or the receivers (SB3; SB4) comprise a component (P3; DZB4) defining a threshold voltage opposing the flow of the electric current through the cable (C1).

2. The installation for exchanging information as claimed in claim 1, wherein the component (P3) defining a threshold voltage opposing the flow of the electric current through the cable (C1) is a dry-cell or an electric accumulator (P3).

3. The installation for exchanging information as claimed in claim 1, wherein the component (DZB4) defining a threshold voltage opposing the flow of the electric current through the cable (C1) comprises a Zener diode (DZB4) supplied with a continuous current, such that between its terminals it exhibits a voltage substantially equal to its Zener voltage even in the absence of current in the cable (C1).

4. The installation for exchanging information as claimed in claim 3, wherein the threshold voltage opposing the flow of the electric current through the cable (C1) is the sum of the Zener voltage of the Zener diode (DZB4) and of the emitter-base voltage of a transistor (TB4) whose emitter is linked to the anode of the Zener diode (DZB4).

5. The installation for exchanging information as claimed in claim 1, wherein the threshold voltage is greater than 2 volts.

6. The installation for exchanging information as claimed in claim 2, wherein the threshold voltage is greater than 2 volts.

7. The installation for exchanging information as claimed in claim 3, wherein the threshold voltage is greater than 2 volts.

8. The installation for exchanging information as claimed in claim 4, wherein the threshold voltage is greater than 2 volts.
